(19) United States
(12) Patent Application Publication
(10) Pub. No.: US 2026/0190506 A1
(43) Pub. Date: Jul. 2, 2026

(54) LIDAR Sensor System with Improved Photodiode

(71) Applicant: Aurora Operations, Inc., Pittsburgh, PA (US)

(72) Inventors: Xue Liu, San Jose, CA (US); Andrew Steil Michaels, Los Altos, CA (US)

(21) Appl. No.: 19/005,183

(22) Filed: Dec. 30, 2024

(51) Int. Cl. H10F 30/222; G01S 7/481; H10F 77/1226; H10F 77/20; H10F 77/40

(52) U.S. Cl. CPC H10F 30/222; G01S 7/4816; H10F 77/1226; H10F 77/206; H10F 77/413

(57) ABSTRACT

A light detection and ranging (LIDAR) system for an autonomous vehicle can include a photodiode for detecting light. The photodiode includes a first semiconductor layer configured to form a waveguide region for receipt of initial light into the photodiode and a first region of the photodiode coupled to the waveguide region. The photodiode also includes a second semiconductor layer formed on a portion of the first semiconductor layer, wherein the first semiconductor layer and the second semiconductor layer form a second region of the photodiode coupled to the first region. Light propagating into the first region of the photodiode comprises one or more first optical modes and light propagating into the second region of the photodiode comprises one or more second optical modes, the second optical modes being different from the first optical modes.

### BACKGROUND

Light detection and ranging (LIDAR) systems use lasers to create three-dimensional representations of surrounding environments. A LIDAR system includes at least one emitter paired with a receiver to form a channel, though an array of channels may be used to expand the field of view of the LIDAR system. During operation, each channel emits a laser beam into the environment. The laser beam reflects off of an object within the surrounding environment, and the reflected laser beam is detected by the receiver. A single channel provides a single point of ranging information. Collectively, channels are combined to create a point cloud that corresponds to a three-dimensional representation of the surrounding environment.

The emitter and/or receiver often includes photonic circuitry formed on a semiconductor substrate such as a silicon die. Silicon photonics dies can provide for precise formation of the photonic circuitry through, for example, photolithography. Other optical components of a LIDAR sensor system may also be formed on semiconductor substrates, while still others are formed on or connected to components made using other semiconductor materials such as, for example, a group III-V semiconductor, gallium arsenide (GaAs), and/or other suitable materials.

### SUMMARY

Aspects and advantages of implementations of the present disclosure will be set forth in part in the following description, or may be learned from the description, or may be learned through practice of the implementations.

Example aspects of the present disclosure are directed to LIDAR systems. As further described herein, the LIDAR systems can be used by various devices and platforms (e.g., robotic platforms, etc.) to improve the ability of the devices and platforms to perceive their environment and perform functions in response thereto (e.g., autonomously navigating through the environment).

The present application relates to an improved architecture and optical mode configuration for a silicon-germanium photodiode. Input optical field engineering and contact metal engineering can be employed individually or collectively to yield improved architecture configurations. Such improved photodiodes provide light detection with greater optical efficiency and improved device performance. These advantages can be realized in a variety of silicon photonics applications, such as, but not limited to, data communication systems and light detection and ranging (LIDAR) sensor systems.

In one example embodiment, a photodiode includes a first semiconductor layer (e.g., a silicon base layer) forming in part a waveguide region configured for receipt of initial light into the photodiode. The silicon base layer also forms a first region of the photodiode referred to as the multi-modal interference (MMI) region. The first region can be generally rectangular in shape or generally triangular in shape. The first region can be characterized by a first transmission length and formed without a metal contact thereon. The first region is coupled to the waveguide region such that light provided as input to the waveguide region flows out of the waveguide region and into the first region. A second semiconductor layer (e.g., a germanium layer) is formed and positioned on a portion of the silicon base layer. The portion of the silicon layer and the germanium layer combine to form a second region of the photodiode referred to as an absorption region. The second region can be characterized by a second transmission length and formed with at least a first metal contact thereon. The second region is coupled to the first region such that light exiting the first region flows into the second region. Light flow through the entirety of the photodiode can include the following sequence of operations: (i) light enters the waveguide region of the photodiode through an input port at a first end of the waveguide region and travels to a second opposing end of the waveguide region; (ii) light expands in the first (MMI) region of the photodiode as it travels from a first end to an opposing second end of the first region along the first transmission length; and (iii) light is absorbed from the first semiconductor layer into the second semiconductor layer as it travels into the second region along the second transmission length.

Portions of the silicon and germanium layers can be doped with one or more doping materials to create extrinsic semiconductor areas intended for formation of electrical circuit elements. For example, the germanium layer can include a doped p-type region, on top of which the first metal contact is formed to create an anode (input terminal) for the photodiode. The germanium layer can include a doped n-type region on top of which a second metal contact is formed to create a cathode (output terminal) for the photodiode. Collectively, the doped p-type region and doped n-type region form the p-n junction of the photodiode, which converts optical light into electrical current.

The configuration of the first semiconductor layer to include a first (MMI) region of the photodiode is designed to engineer a propagation pattern defining or otherwise caused by one or more orders of optical mode(s) of light received by the photodiode. In instances where a single optical mode of light is present at a semiconductor layer, the propagation pattern can refer to the optical mode itself. The initial light received by the waveguide region can be characterized by a first propagation pattern that is substantially singular in nature, elliptical in shape, and that is focused about a first central location along a cross-section of the photodiode. The initial light is received at a first end of the MMI region of the photodiode and propagates through the MMI region to become modified light at a second end of the MMI region of the photodiode. The second end of the MMI region can be opposite the first end of the MMI region (e.g., along a dimension of the MMI region). The modified light can be characterized by a second propagation pattern that is substantially dual in nature and focused about two distributed locations, namely a first peripheral location and a second peripheral location along a cross-section of the photodiode. For instance, the first peripheral location and the second peripheral location can respectively be or include lobes of the second propagation pattern. The first peripheral location associated with the second optical mode is towards a first side of the first central location associated with the first optical mode, while the second peripheral location associated with the second optical mode is towards a second side (opposite the first side) of the first central location associated with the first optical mode.

By intentionally modifying and distributing the optical mode(s) of the light, modified light can then enter the absorption region of the photodiode at locations that are distributed away from the metal contact on top of the germanium layer (e.g., the anode). Strategic positioning of the MMI region before the absorption region of the photodiode serves to beneficially facilitate the redistribution of the input optical power. By selecting a specific location that ensures minimal overlap with the contact metal, absorption efficiency can be enhanced and potentially detrimental effects of optical absorption can be mitigated. The dimensions, length, and shape of the MMI region can be tailored and optimized to achieve a desired redistribution of the input optical power and reduce back-reflection into the entrance port.

In additional or alternative implementations, the metal contact forming the anode and/or cathode portions of the photodiode can be configured to further enhance absorption efficiency of the photodiode. Particular design of the metal contact(s) can include selected contact geometry, thickness, or placement to reduce potential optical losses. For example, first and second metal contacts forming the anode of the photodiode can be positioned at respective locations across a surface of the photodiode that are offset relative to the focused locations of the optical mode. Metal contact engineering optimization techniques can be applied individually or in combination to achieve the desired reduction in optical losses and enhance the absorption efficiency of the photodiode.

Aspects of the present disclosure can provide a number of technical effects and benefits. As one example, including an improved photodiode with specifically engineered optical modes (e.g., by including an MMI region for transforming light from a first propagation pattern to a second propagation pattern) can increase the efficiency of photodiode operation based on light sensitivity. By increasing a photodiode's ability to effectively capture amounts of incoming light, the accuracy of a photodiode's optical measurement performance is also increased. Better optical signal measurements at a photodiode help to increase receiver signal processing in communications systems, LIDAR systems, and other sensor systems in which the photodiodes are employed,

For example, in an aspect, the present disclosure provides a photodiode that includes a first semiconductor layer configured to form a waveguide region for receipt of initial light into the photodiode and a first region of the photodiode coupled to the waveguide region. The photodiode also includes a second semiconductor layer formed on a portion of the first semiconductor layer, wherein the first semiconductor layer and the second semiconductor layer form a second region of the photodiode coupled to the first region. Light propagating into the first region of the photodiode includes one or more first optical modes and light propagating into the second region of the photodiode includes one or more second optical modes, the second optical modes being different from the first optical modes.

In some implementations, the one or more first optical modes propagating into the first region of the photodiode provide at the first region a first propagation pattern that is substantially singular in nature and focused about a first central location along a cross-section of the photodiode.

In some implementations, the one or more second optical modes propagating into the second region of the photodiode provide at the second region a second propagation pattern that is substantially dual in nature and focused about two distributed locations corresponding to a first peripheral location and a second peripheral location along the cross-section of the photodiode.

In some implementations, the photodiode also includes a first metal contact configured as a first terminal for the photodiode formed on a portion of the second semiconductor layer corresponding to the second region.

In some implementations, the first region is formed without a metal contact thereon.

In some implementations, the first metal contact is formed on a peripheral portion of the second semiconductor layer corresponding to the second region.

In some implementations, the second semiconductor layer includes a doped p-type region on top of which the first metal contact is formed to create the first terminal for the photodiode.

In some implementations, the photodiode also includes a second metal contact configured as a second terminal for the photodiode formed on a portion of the first semiconductor layer.

In some implementations, the first semiconductor layer includes a doped n-type region on top of which the second metal contact is formed to create the second terminal for the photodiode.

In some implementations, the doped p-type region and the doped n-type region form a p-n junction of the photodiode, the p-n junction configured to convert optical light into electrical current.

In some implementations, the first semiconductor layer includes silicon and the second semiconductor layer includes germanium.

In another aspect, the present disclosure provides a light detection and ranging (LIDAR) system that includes a photodiode. The photodiode of the LIDAR system includes a first semiconductor layer configured to form a waveguide region for receipt of initial light into the photodiode and a first region of the photodiode coupled to the waveguide region. The photodiode of the LIDAR system also includes a second semiconductor layer formed on a portion of the first semiconductor layer, wherein the first semiconductor layer and the second semiconductor layer form a second region of the photodiode coupled to the first region. Light propagating into the first region of the photodiode comprises one or more first optical modes and light propagating into the second region of the photodiode includes one or more second optical modes, the second optical modes being different from the first optical modes.

In some implementations, the one or more first optical modes propagating into the first region of the photodiode provide at the first region a first propagation pattern that is substantially singular in nature and focused about a first central location along a cross-section of the photodiode.

In some implementations, the one or more second optical modes of light operable to propagate into the second region of the photodiode provide at the second region a second propagation pattern that is substantially dual in nature and focused about two distributed locations corresponding to a first peripheral location and a second peripheral location along the cross-section of the photodiode.

In some implementations, the photodiode of the LIDAR system also includes a first metal contact configured as a first terminal for the photodiode formed on a portion of the second semiconductor layer corresponding to the second region.

In some implementations, the first region of the photodiode of the LIDAR system is formed without a metal contact thereon.

In some implementations, the first metal contact is formed on a peripheral portion of the second semiconductor layer corresponding to the second region.

In some implementations, the photodiode of the LIDAR system also includes a second metal contact configured as a second terminal for the photodiode formed on a portion of the first semiconductor layer.

In some implementations, the first semiconductor layer of the photodiode includes silicon and the second semiconductor layer of the photodiode includes germanium.

In another aspect, the present disclosure provides a detector that includes a photodiode. The photodiode of the detector includes a first semiconductor layer configured to form a waveguide region for receipt of initial light into the photodiode and a first region of the photodiode coupled to the waveguide region. The photodiode of the LIDAR system also includes a second semiconductor layer formed on a portion of the first semiconductor layer, wherein the first semiconductor layer and the second semiconductor layer form a second region of the photodiode coupled to the first region. Light propagating into the first region of the photodiode includes one or more first optical modes and light propagating into the second region of the photodiode includes one or more second optical modes, the second optical modes being different from the first optical modes.

Other example aspects of the present disclosure are directed to other systems, methods, apparatuses, tangible non-transitory computer-readable media, and devices for manufacturing semiconductor devices for a LIDAR system, as well as motion prediction and/or operation of a device (e.g., a vehicle) including a LIDAR system having a detector with one or photodiodes or similar semiconductor-based light-sensitive devices according to example aspects of the present disclosure.

These and other features, aspects and advantages of various implementations of the present disclosure will become better understood with reference to the following description and appended claims. The accompanying drawings, which are incorporated in and constitute a part of this specification, illustrate implementations of the present disclosure and, together with the description, serve to explain the related principles.

### BRIEF DESCRIPTION OF THE DRAWINGS

FIG. 1 depicts a block diagram of an example system according to the present disclosure.

FIG. 2 depicts a block diagram of an example LIDAR system according to the present disclosure.

FIG. 3A provides a perspective view of a first example photodiode according to the present disclosure.

FIG. 3B provides a top view of a first example photodiode according to the present disclosure.

FIG. 3C provides a side view of a first example photodiode according to the present disclosure.

FIG. 4A provides a perspective view of a second example photodiode according to the present disclosure.

FIG. 4B provides a top view of a second example photodiode according to the present disclosure.

FIG. 4C provides a side view of a second example photodiode according to the present disclosure.

FIG. 5A provides a cross-sectional view of aspects of a first example photodiode according to the present disclosure.

FIG. 5B provides a cross-sectional view of aspects of a second example photodiode according to the present disclosure.

FIG. 6 provides a cross-sectional view of various regions of a photodiode according to the present disclosure.

FIG. 7A depicts aspects of optical mode within a first example photodiode according to the present disclosure.

FIG. 7B depicts aspects of optical mode within a second example photodiode according to the present disclosure.

FIG. 8 depicts aspects of an engineered optical mode within a first example photodiode according to the present disclosure.

FIG. 9A provides a graphical representation of a first optical mode according to the present disclosure.

FIG. 9B provides a graphical representation of a second optical mode according to the present disclosure.

FIG. 10 provides a flowchart of a method of forming an example photodiode according to the present disclosure.

### DETAILED DESCRIPTION

The following describes the technology of this disclosure within the context of an autonomous vehicle for example purposes only. As described herein, the technology is not limited to an autonomous vehicle and can be implemented within other robotic and computing systems as well as various devices. For example, the systems and methods disclosed herein can be implemented in a variety of ways including, but not limited to, a computer-implemented method, an autonomous vehicle system, an autonomous vehicle control system, a robotic platform system, a general robotic device control system, a computing device, etc.

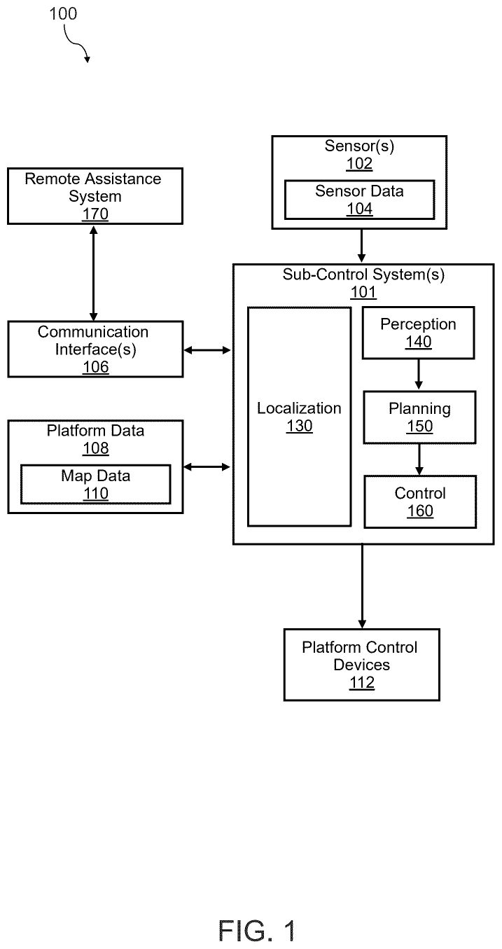

With reference to FIGS. 1-10, example implementations of the present disclosure are discussed in further detail. FIG. 1 depicts a block diagram of an example autonomous vehicle control system 100 for an autonomous vehicle according to some implementations of the present disclosure. The autonomous vehicle control system 100 can be implemented by a computing system of an autonomous vehicle. The autonomous vehicle control system 100 can include one or more sub-control systems 101 that operate to obtain inputs from sensor(s) 102 or other input devices of the autonomous vehicle control system 100. In some implementations, the sub-control system(s) 101 can additionally obtain platform data 108 (e.g., map data 110) from local or remote storage. The sub-control system(s) 101 can generate control outputs for controlling the autonomous vehicle (e.g., through platform control devices 112, etc.) based on sensor data 104, map data 110, or other data. The sub-control system 101 may include different subsystems for performing various autonomy operations. The subsystems may include a localization system 130, a perception system 140, a planning system 150, and a control system 160. The localization system 130 can determine the location of the autonomous vehicle within its environment; the perception system 140 can detect, classify, and track objects and actors in the environment; the planning system 150 can determine a trajectory for the autonomous vehicle; and the control system 160 can translate the trajectory into vehicle controls for controlling the autonomous vehicle. The sub-control system(s) 101 can be implemented by one or more onboard computing system(s) (also referred to herein as subsystems). The subsystems can include one or more processors and one or more memory devices. The one or more memory devices can store instructions executable by the one or more processors to cause the one or more processors to perform operations or functions associated with the subsystems. The computing resources of the sub-control system(s) 101 can be shared among its subsystems, or a subsystem can have a set of dedicated computing resources.

In some implementations, the autonomous vehicle control system 100 can be implemented for or by an autonomous vehicle (e.g., a ground-based autonomous vehicle). The autonomous vehicle control system 100 can perform various processing techniques on inputs (e.g., the sensor data 104, the map data 110) to perceive and understand the vehicle's surrounding environment and generate an appropriate set of control outputs to implement a vehicle motion plan (e.g., including one or more trajectories) for traversing the vehicle's surrounding environment. In some implementations, an autonomous vehicle implementing the autonomous vehicle control system 100 can drive, navigate, operate, etc. with minimal or no interaction from a human operator (e.g., driver, pilot, etc.).

In some implementations, the autonomous vehicle can be configured to operate in a plurality of operating modes. For instance, the autonomous vehicle can be configured to operate in a fully autonomous (e.g., self-driving, etc.) operating mode in which the autonomous vehicle is controllable without user input (e.g., can drive and navigate with no input from a human operator present in the autonomous vehicle or remote from the autonomous vehicle, etc.). The autonomous vehicle can operate in a semi-autonomous operating mode in which the autonomous vehicle can operate with some input from a human operator present in the autonomous vehicle (or a human operator that is remote from the autonomous vehicle). In some implementations, the autonomous vehicle can enter into a manual operating mode in which the autonomous vehicle is fully controllable by a human operator (e.g., human driver, etc.) and can be prohibited or disabled (e.g., temporary, permanently, etc.) from performing autonomous navigation (e.g., autonomous driving, etc.). The autonomous vehicle can be configured to operate in other modes such as, for example, park or sleep modes (e.g., for use between tasks such as waiting to provide a trip/service, recharging, etc.). In some implementations, the autonomous vehicle can implement vehicle operating assistance technology (e.g., collision mitigation system, power assist steering, etc.), for example, to help assist the human operator of the autonomous vehicle (e.g., while in a manual mode, etc.).

The autonomous vehicle control system 100 can be located onboard (e.g., on or within) an autonomous vehicle and can be configured to operate the autonomous vehicle in various environments. The environment may be a real-world environment or a simulated environment. In some implementations, one or more simulation computing devices can simulate one or more of: the sensors 102, the sensor data 104, communication interface(s) 106, the platform data 108, or the platform control devices 112 for simulating operation of the autonomous vehicle control system 100.

In some implementations, the sub-control system(s) 101 can communicate with one or more networks or other systems with communication interface(s) 106. The communication interface(s) 106 can include any suitable components for interfacing with one or more network(s), including, for example, transmitters, receivers, ports, controllers, antennas, or other suitable components that can help facilitate communication. In some implementations, the communication interface(s) 106 can include a plurality of components (e.g., antennas, transmitters, or receivers, etc.) that allow it to implement and utilize various communication techniques (e.g., multiple-input, multiple-output (MIMO) technology, etc.).

In some implementations, the sub-control system(s) 101 can use the communication interface(s) 106 to communicate with one or more computing devices that are remote from the autonomous vehicle over one or more network(s). For instance, in some examples, one or more inputs, data, or functionalities of the sub-control system(s) 101 can be supplemented or substituted by a remote system communicating over the communication interface(s) 106. For instance, in some implementations, the map data 110 can be downloaded over a network to a remote system using the communication interface(s) 106. In some examples, one or more of the localization system 130, the perception system 140, the planning system 150, or the control system 160 can be updated, influenced, nudged, communicated with, etc. by a remote system for assistance, maintenance, situational response override, management, etc.

The sensor(s) 102 can be located onboard the autonomous platform. In some implementations, the sensor(s) 102 can include one or more types of sensor(s). For instance, one or more sensors can include image capturing device(s) (e.g., visible spectrum cameras, infrared cameras, etc.). Additionally or alternatively, the sensor(s) 102 can include one or more depth capturing device(s). For example, the sensor(s) 102 can include one or more LIDAR sensor(s) or radio detection and ranging (RADAR) sensor(s). The sensor(s) 102 can be configured to generate point data descriptive of at least a portion of a three-hundred-and-sixty-degree view of the surrounding environment. The point data can be point cloud data (e.g., three-dimensional LIDAR point cloud data, RADAR point cloud data). In some implementations, one or more of the sensor(s) 102 for capturing depth information can be fixed to a rotational device in order to rotate the sensor(s) 102 about an axis. The sensor(s) 102 can be rotated about the axis while capturing data in interval sector packets descriptive of different portions of a three-hundred-and-sixty-degree view of a surrounding environment of the autonomous platform. In some implementations, one or more of the sensor(s) 102 for capturing depth information can be solid state.

The sensor(s) 102 can be configured to capture the sensor data 104 indicating or otherwise being associated with at least a portion of the environment of the autonomous vehicle. The sensor data 104 can include image data (e.g., 2D camera data, video data, etc.), RADAR data, LIDAR data (e.g., 3D point cloud data, etc.), audio data, or other types of data. In some implementations, the sub-control system(s) 101 can obtain input from additional types of sensors, such as inertial measurement units (IMUs), altimeters, inclinometers, odometry devices, location or positioning devices (e.g., GPS, compass), wheel encoders, or other types of sensors. In some implementations, the sub-control system(s) 101 can obtain sensor data 104 associated with particular component(s) or system(s) of the autonomous vehicle. This sensor data 104 can indicate, for example, wheel speed, component temperatures, steering angle, cargo or passenger status, etc. In some implementations, the sub-control system(s) 101 can obtain sensor data 104 associated with ambient conditions, such as environmental or weather conditions. In some implementations, the sensor data 104 can include multi-modal sensor data. The multi-modal sensor data can be obtained by at least two different types of sensor(s) (e.g., of the sensors 102) and can indicate static and/or dynamic object(s) or actor(s) within an environment of the autonomous vehicle. The multi-modal sensor data can include at least two types of sensor data (e.g., camera and LIDAR data). In some implementations, the autonomous vehicle can utilize the sensor data 104 for sensors that are remote from (e.g., offboard) the autonomous vehicle. This can include for example, sensor data 104 captured by a different autonomous vehicle.

The sub-control system(s) 101 can obtain the map data 110 associated with an environment in which the autonomous vehicle was, is, or will be located. The map data 110 can provide information about an environment or a geographic area. For example, the map data 110 can provide information regarding the identity and location of different travel ways (e.g., roadways, etc.), travel way segments (e.g., road segments, etc.), buildings, or other items or objects (e.g., lampposts, crosswalks, curbs, etc.); the location and directions of boundaries or boundary markings (e.g., the location and direction of traffic lanes, parking lanes, turning lanes, bicycle lanes, other lanes, etc.); traffic control data (e.g., the location and instructions of signage, traffic lights, other traffic control devices, etc.); obstruction information (e.g., temporary or permanent blockages, etc.); event data (e.g., road closures/traffic rule alterations due to parades, concerts, sporting events, etc.); nominal vehicle path data (e.g., indicating an ideal vehicle path such as along the center of a certain lane, etc.); or any other map data that provides information that assists an autonomous vehicle in understanding its surrounding environment and its relationship thereto. In some implementations, the map data 110 can include high-definition map information. Additionally or alternatively, the map data 110 can include sparse map data (e.g., lane graphs, etc.). In some implementations, the sensor data 104 can be fused with or used to update the map data 110 in real time.

The sub-control system(s) 101 can include the localization system 130, which can provide an autonomous vehicle with an understanding of its location and orientation in an environment. In some examples, the localization system 130 can support one or more other subsystems of the sub-control system(s) 101, such as by providing a unified local reference frame for performing, e.g., perception operations, planning operations, or control operations.

In some implementations, the localization system 130 can determine a current position of the autonomous vehicle. A current position can include a global position (e.g., respecting a georeferenced anchor, etc.) or relative position (e.g., respecting objects in the environment, etc.). The localization system 130 can generally include or interface with any device or circuitry for analyzing a position or change in position of an autonomous vehicle. For example, the localization system 130 can determine position by using one or more of: inertial sensors (e.g., inertial measurement unit(s), etc.), a satellite positioning system, radio receivers, networking devices (e.g., based on IP address, etc.), triangulation or proximity to network access points or other network components (e.g., cellular towers, Wi-Fi access points, etc.), or other suitable techniques. The position of the autonomous vehicle can be used by various subsystems of the sub-control system(s) 101 or provided to a remote computing system (e.g., using the communication interface(s) 106).

In some implementations, the localization system 130 can register relative positions of elements of a surrounding environment of the autonomous vehicle with recorded positions in the map data 110. For instance, the localization system 130 can process the sensor data 104 (e.g., LIDAR data, RADAR data, camera data, etc.) for aligning or otherwise registering to a map of the surrounding environment (e.g., from the map data 110) to understand the autonomous vehicle's position within that environment. Accordingly, in some implementations, the autonomous vehicle can identify its position within the surrounding environment (e.g., across six axes, etc.) based on a search over the map data 110. In some implementations, given an initial location, the localization system 130 can update the autonomous vehicle's location with incremental re-alignment based on recorded or estimated deviations from the initial location. In some implementations, a position can be registered directly within the map data 110.

In some implementations, the map data 110 can include a large volume of data subdivided into geographic tiles, such that a desired region of a map stored in the map data 110 can be reconstructed from one or more tiles. For instance, a plurality of tiles selected from the map data 110 can be stitched together by the sub-control system 101 based on a position obtained by the localization system 130 (e.g., a number of tiles selected in the vicinity of the position).

In some implementations, the localization system 130 can determine positions (e.g., relative or absolute) of one or more attachments or accessories for an autonomous vehicle. For instance, an autonomous vehicle can be associated with a cargo platform, and the localization system 130 can provide positions of one or more points on the cargo platform. For example, a cargo platform can include a trailer or other device towed or otherwise attached to or manipulated by an autonomous vehicle, and the localization system 130 can provide for data describing the position (e.g., absolute, relative, etc.) of the autonomous vehicle as well as the cargo platform. Such information can be obtained by the other autonomy systems to help operate the autonomous vehicle.

The sub-control system(s) 101 can include the perception system 140, which can allow an autonomous platform to detect, classify, and track objects and actors in its environment. Environmental features or objects perceived within an environment can be those within the field of view of the sensor(s) 102 or predicted to be occluded from the sensor(s) 102. This can include object(s) not in motion or not predicted to move (static objects) or object(s) in motion or predicted to be in motion (dynamic objects/actors).

The perception system 140 can determine one or more states (e.g., current or past state(s), etc.) of one or more objects that are within a surrounding environment of an autonomous vehicle. For example, state(s) can describe (e.g., for a given time, time period, etc.) an estimate of an object's current or past location (also referred to as position); current or past speed/velocity; current or past acceleration; current or past heading; current or past orientation; size/footprint (e.g., as represented by a bounding shape, object highlighting, etc.); classification (e.g., pedestrian class vs. vehicle class vs. bicycle class, etc.); the uncertainties associated therewith; or other state information. In some implementations, the perception system 140 can determine the state(s) using one or more algorithms or machine-learned models configured to identify/classify objects based on inputs from the sensor(s) 102. The perception system can use different modalities of the sensor data 104 to generate a representation of the environment to be processed by the one or more algorithms or machine-learned models. In some implementations, state(s) for one or more identified or unidentified objects can be maintained and updated over time as the autonomous vehicle continues to perceive or interact with the objects (e.g., maneuver with or around, yield to, etc.). In this manner, the perception system 140 can provide an understanding about a current state of an environment (e.g., including the objects therein, etc.) informed by a record of prior states of the environment (e.g., including movement histories for the objects therein). Such information can be helpful as the autonomous vehicle plans its motion through the environment.

The sub-control system(s) 101 can include the planning system 150, which can be configured to determine how the autonomous platform is to interact with and move within its environment. The planning system 150 can determine one or more motion plans for an autonomous platform. A motion plan can include one or more trajectories (e.g., motion trajectories) that indicate a path for an autonomous vehicle to follow. A trajectory can be of a certain length or time range. The length or time range can be defined by the computational planning horizon of the planning system 150. A motion trajectory can be defined by one or more waypoints (with associated coordinates). The waypoint(s) can be future location(s) for the autonomous platform. The motion plans can be continuously generated, updated, and considered by the planning system 150.

The planning system 150 can determine a strategy for the autonomous platform. A strategy may be a set of discrete decisions (e.g., yield to actor, reverse yield to actor, merge, lane change) that the autonomous platform makes. The strategy may be selected from a plurality of potential strategies. The selected strategy may be a lowest cost strategy as determined by one or more cost functions. The cost functions may, for example, evaluate the probability of a collision with another actor or object.

The planning system 150 can determine a desired trajectory for executing a strategy. For instance, the planning system 150 can obtain one or more trajectories for executing one or more strategies. The planning system 150 can evaluate trajectories or strategies (e.g., with scores, costs, rewards, constraints, etc.) and rank them. For instance, the planning system 150 can use forecasting output(s) that indicate interactions (e.g., proximity, intersections, etc.) between trajectories for the autonomous platform and one or more objects to inform the evaluation of candidate trajectories or strategies for the autonomous platform. In some implementations, the planning system 150 can utilize static cost(s) to evaluate trajectories for the autonomous platform (e.g., “avoid lane boundaries,” “minimize jerk,” etc.). Additionally or alternatively, the planning system 150 can utilize dynamic cost(s) to evaluate the trajectories or strategies for the autonomous platform based on forecasted outcomes for the current operational scenario (e.g., forecasted trajectories or strategies leading to interactions between actors, forecasted trajectories or strategies leading to interactions between actors and the autonomous platform, etc.). The planning system 150 can rank trajectories based on one or more static costs, one or more dynamic costs, or a combination thereof. The planning system 150 can select a motion plan (and a corresponding trajectory) based on a ranking of a plurality of candidate trajectories. In some implementations, the planning system 150 can select a highest ranked candidate, or a highest ranked feasible candidate.

The planning system 150 can then validate the selected trajectory against one or more constraints before the trajectory is executed by the autonomous platform.

To help with its motion planning decisions, the planning system 150 can be configured to perform a forecasting function. The planning system 150 can forecast future state(s) of the environment. This can include forecasting the future state(s) of other actors in the environment. In some implementations, the planning system 150 can forecast future state(s) based on current or past state(s) (e.g., as developed or maintained by the perception system 140). In some implementations, future state(s) can be or include forecasted trajectories (e.g., positions over time) of the objects in the environment, such as other actors. In some implementations, one or more of the future state(s) can include one or more probabilities associated therewith (e.g., marginal probabilities, conditional probabilities). For example, the one or more probabilities can include one or more probabilities conditioned on the strategy or trajectory options available to the autonomous vehicle. Additionally or alternatively, the probabilities can include probabilities conditioned on trajectory options available to one or more other actors.

To implement selected motion plan(s), the sub-control system(s) 101 can include a control system 160 (e.g., a vehicle control system). Generally, the control system 160 can provide an interface between the sub-control system(s) 101 and the platform control devices 112 for implementing the strategies and motion plan(s) generated by the planning system 150. For instance, the control system 160 can implement the selected motion plan/trajectory to control the autonomous platform's motion through its environment by following the selected trajectory (e.g., the waypoints included therein). The control system 160 can, for example, translate a motion plan into instructions for the appropriate platform control devices 112 (e.g., acceleration control, brake control, steering control, etc.). By way of example, the control system 160 can translate a selected motion plan into instructions to adjust a steering component (e.g., a steering angle) by a certain number of degrees, apply a certain magnitude of braking force, increase/decrease speed, etc. In some implementations, the control system 160 can communicate with the platform control devices 112 through communication channels including, for example, one or more data buses (e.g., controller area network (CAN), etc.), onboard diagnostics connectors (e.g., OBD-II, etc.), or a combination of wired or wireless communication links. The platform control devices 112 can send or obtain data, messages, signals, etc. to or from the sub-control system(s) 101 (or vice versa) through the communication channel(s).

The sub-control system(s) 101 can receive, through communication interface(s) 106, assistive signal(s) from remote assistance system 170. Remote assistance system 170 can communicate with the sub-control system(s) 101 over a network. In some implementations, the sub-control system(s) 101 can initiate a communication session with the remote assistance system 170. For example, the sub-control system(s) 101 can initiate a session based on or in response to a trigger. In some implementations, the trigger may be an alert, an error signal, a map feature, a request, a location, a traffic condition, a road condition, etc.

After initiating the session, the sub-control system(s) 101 can provide context data to the remote assistance system 170. The context data may include sensor data 104 and state data of the autonomous vehicle. For example, the context data may include a live camera feed from a camera of the autonomous vehicle and the autonomous vehicle's current speed. An operator (e.g., human operator) of the remote assistance system 170 can use the context data to select assistive signals. The assistive signal(s) can provide values or adjustments for various operational parameters or characteristics for the sub-control system(s) 101. For instance, the assistive signal(s) can include way points (e.g., a path around an obstacle, lane change, etc.), velocity or acceleration profiles (e.g., speed limits, etc.), relative motion instructions (e.g., convoy formation, etc.), operational characteristics (e.g., use of auxiliary systems, reduced energy processing modes, etc.), or other signals to assist the sub-control system(s) 101.

The sub-control system(s) 101 can use the assistive signal(s) for input into one or more autonomy subsystems for performing autonomy functions. For instance, the planning system 150 can receive the assistive signal(s) as an input for generating a motion plan. For example, assistive signal(s) can include constraints for generating a motion plan. Additionally or alternatively, assistive signal(s) can include cost or reward adjustments for influencing motion planning by the planning system 150. Additionally or alternatively, assistive signal(s) can be considered by the sub-control system(s) 101 as suggestive inputs for consideration in addition to other received data (e.g., sensor inputs, etc.).

The sub-control system(s) 101 may be platform agnostic, and the control system 160 can provide control instructions to platform control devices 112 for a variety of different platforms for autonomous movement (e.g., a plurality of different autonomous platforms fitted with autonomous control systems). This can include a variety of different types of autonomous vehicles (e.g., sedans, vans, SUVs, trucks, electric vehicles, combustion power vehicles, etc.) from a variety of different manufacturers/developers that operate in various different environments and, in some implementations, perform one or more vehicle services.

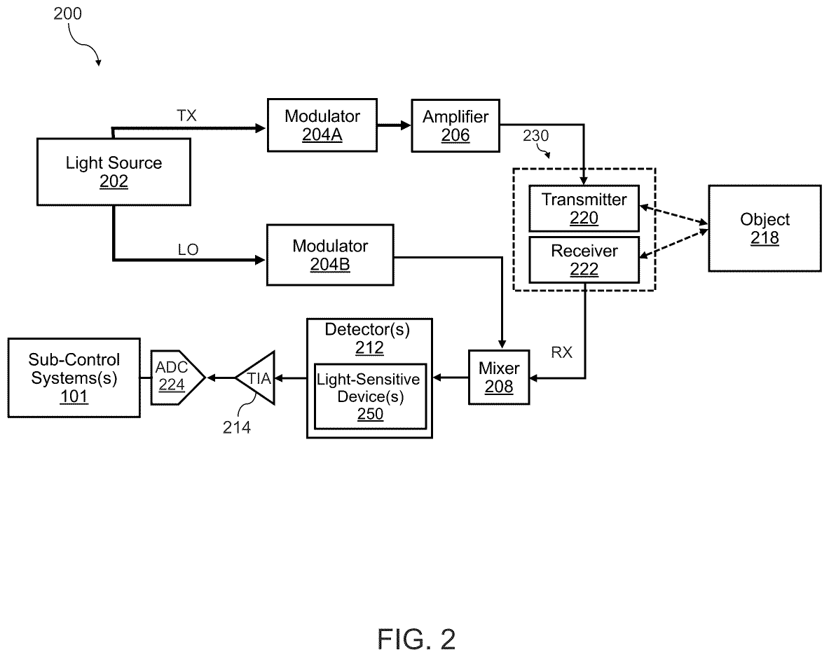

FIG. 2 is a block diagram illustrating an example LIDAR system for autonomous vehicles, according to some implementations. The environment includes a LIDAR system 200 that includes a transmit (Tx) path and a receive (Rx) path. The Tx path includes one or more Tx input/output ports (e.g., channels), and the Rx path includes one or more Rx input/output ports (e.g., channels). In some implementations, a semiconductor substrate and/or semiconductor package may include the Tx path and/or the Rx path. In some implementations, the semiconductor substrate and/or semiconductor package may include at least one of silicon photonics circuitry, a programmable logic controller (PLC), or group III-V semiconductor circuitry.

In some implementations, a first semiconductor substrate and/or a first semiconductor package may include the Tx path and a second semiconductor substrate and/or a second semiconductor package may include the Rx path. In some arrangements, the Rx input/output ports and/or the Tx input/output ports may occur (or be formed/disposed/located/placed) along one or more edges of one or more semiconductor substrates and/or semiconductor packages.

The LIDAR system 200 can be coupled to one or more sub-control system(s) (e.g., the sub-control system(s) 101 of FIG. 1). In some implementations, the sub-control system(s) 101 may be coupled to the Rx path via the one or more Rx input/output ports. For instance, the sub-control system(s) 101 can receive LIDAR outputs from the LIDAR system 200. The sub-control system(s) 101 can control a vehicle (e.g., an autonomous vehicle) based on the LIDAR outputs.

The Tx path may include a light source (e.g., light source) 202, a modulator 204A, a modulator 204B, an amplifier 206, and one or more transmitters 220. The Rx path may include one or more receivers 222, a mixer 208, a detector 212, a transimpedance amplifier (TIA) 214, and one or more analog-to-digital converters (ADCs) 224. Although FIG. 2 shows only a select number of components and only one input/output channel, the LIDAR system 200 may include any number of components and/or input/output channels (in any combination) that are interconnected in any arrangement to facilitate combining multiple functions of a LIDAR system, to support the operation of a vehicle.

The light source 202 may be configured to generate a light signal (or beam) that is derived from (or associated with) a local oscillator (LO) signal. In some implementations, the light signal may have an operating wavelength that is equal to or substantially equal to 1550 nanometers. In some implementations, the light signal may have an operating wavelength that is between 1400 nanometers and 1440 nanometers.

The light source 202 may be configured to provide the light signal to the modulator 204A, which is configured to modulate a phase and/or a frequency of the light signal based on a first radio frequency (RF) signal (e.g., an “RF1” signal) to generate a modulated light signal, such as by Continuous Wave (CW) modulation or quasi-CW modulation. The modulator 204A may be configured to send the modulated light signal to the amplifier 206. The amplifier 206 may be configured to amplify the modulated light signal to generate an amplified light signal for transmission via the one or more transmitters 220. The one or more transmitters 220 may include one or more optical waveguides or antennas. In some implementations, modulator 204A and/or modulator 204B may have a bandwidth between 400 megahertz (MHz) and 1000 (MHz).

The LIDAR system 200 includes one or more transmitters 220 and one or more receivers 222. The transmitter(s) 220 and/or receiver(s) 222 can be included in a transceiver 230. The transmitter(s) 220 can provide the transmit beam that it receives from the Tx path into an environment within a given field of view toward an object 218. The one or more receivers 222 can receive a received beam reflected from the object 218 and provide the received beam to the mixer 208 of the Rx path. The one or more receivers 222 may include one or more optical waveguides or antennas. In some arrangements, the one or more transceivers 230 may include a monostatic transceiver or a bistatic transceiver.

The light source 202 may be configured to provide the LO signal to the modulator 204B, which is configured to modulate a phase and/or a frequency of the LO signal based on a second RF signal (e.g., an “RF2” signal) to generate a modulated LO signal (e.g., using Continuous Wave (CW) modulation or quasi-CW modulation) and send the modulated LO signal to the mixer 208 of the Rx path. The mixer 208 may be configured to mix (e.g., combine, multiply, etc.) the modulated LO signal with the returned signal to generate a down-converted signal and send the down-converted signal to the detector 212.

In some arrangements, the mixer 208 may be configured to send the modulated LO signal to the detector 212 (or detectors). The detector 212 may be configured to generate an electrical signal based on the down-converted signal and send the electrical signal to a transimpedance amplifier (TIA) 214. In some arrangements, the detector 212 may be configured to generate an electrical signal based on the down-converted signal and the modulated signal. The TIA 214 may be configured to amplify the electrical signal and send the amplified electrical signal to the sub-control system(s) 101 via the one or more ADCs 224. In some implementations, the TIA 214 may have a peak noise-equivalent power (NEP) that is less than 5 picowatts per square root Hertz (i.e., 5×10-12 Watts per square root Hertz). In some implementations, the TIA 214 may have a gain between 4 kiloohms and 25 kiloohms. In some implementations, detector 212 and/or TIA 214 may have a 3-decibel bandwidth between 80 kilohertz (kHz) and 450 megahertz (MHz). The sub-control system(s) 101 may be configured to determine a distance to the object 218 and/or measure the velocity of the object 218 based on the one or more electrical signals that it receives from the TIA 214 via the one or more ADCs 224.

The detector(s) 212 may include one or more light-sensitive device(s) 250. The light-sensitive device(s) 250 can be devices that are sensitive to light in their operations. For example, the light-sensitive device(s) 250 may operate differently (e.g., output a different signal type or value) depending upon an amount of light in the ambient environment of the light-sensitive device(s) 250. Examples of light-sensitive devices 250 include, but are not limited to, optical circuitry, photodetectors, optical receivers, and photodiodes. According to example aspects of the present disclosure, the optical efficiency of the light-sensitive device(s) 250 can be improved, providing improved performance in detecting the object 218. Example photodiodes 300 and/or 400 described herein can be utilized as a light-sensitive device 250 of FIG. 2. Example aspects of the present disclosure may similarly be applied to other substrates and light-sensitive devices that may be present in the LIDAR system 200, such as light-sensitive devices for feedback or diagnostic systems in the LIDAR system 200.

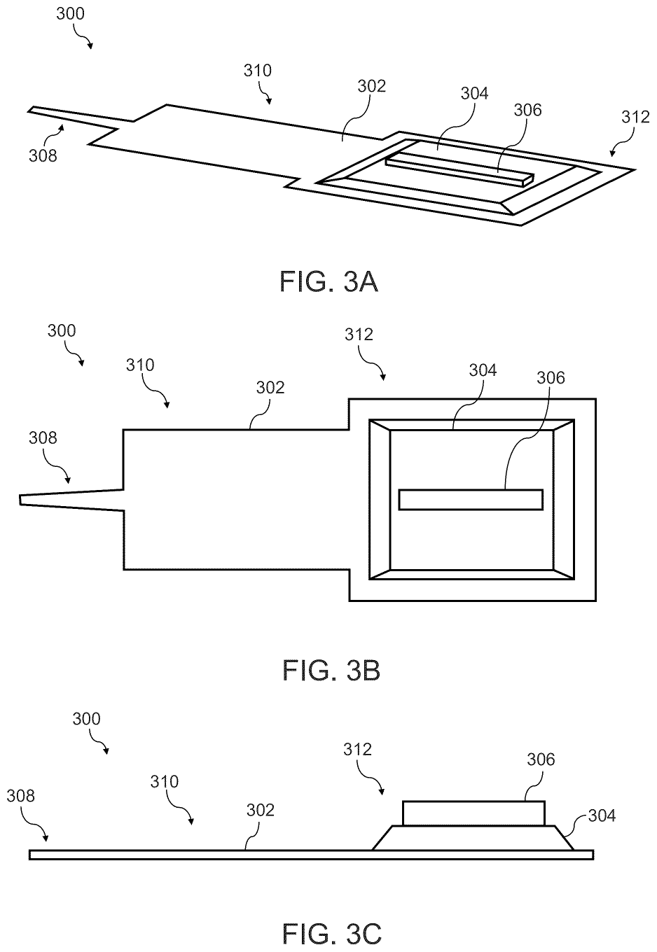

FIGS. 3A-3C variously depict a first example photodiode 300. Photodiode 300 can include a first semiconductor layer 302, a second semiconductor layer 304, and a metal contact 306. The first semiconductor layer (e.g., a silicon base layer) can be configured to form a waveguide region 308 for receipt of initial light into the photodiode 300. The first semiconductor layer 302 can also be configured to form a first region 310 of the photodiode 300. The first region 310 can be characterized by a first transmission length and is formed without a metal contact thereon. The first region 310 is coupled to the waveguide region 308 such that light provided as input to the waveguide region 308 flows out of the waveguide region 308 and into the first region 310.

The first region 310 may be a multi-modal interference (MMI) region. In an MMI region, several higher order optical modes of light propagating through the first region 310 can interact with each other to cause the formation of a desired pattern of light. For example, a first optical mode can have a differing propagation constant from a second optical mode, causing nonuniform propagation of light through the MMI region. The MMI region can be configured such that the nonuniform propagation of light throughout the MMI region causes interference among the propagating light. The interference between optical modes can cause the formation of a desired propagation pattern of light, where the optical mode(s) at the end of the MMI region (e.g., at the end of the first transmission length) includes desired propagation characteristics. This interaction can occur in the MMI region even if the MMI region is formed without some additional processing steps (e.g., doping) relative to the other regions of the first semiconductor layer 302. As one example, in some implementations, a dimension of the first region 310 (e.g., a width) or a shape of the first region 310 may differ from a corresponding dimension (e.g., a width) or shape of the remainder of the first semiconductor layer 302, but the first region 310 may otherwise be identical to the remainder of the first semiconductor layer 302. As another example, in some implementations, the first semiconductor layer 302 may be a single-mode waveguide and may split into a multi-mode waveguide at the first region 310.

In addition, the interaction between the higher order modes of light can be affected by the designed dimensions or shape of the first region 310 (e.g., the MMI region). As one example, in some implementations, the first region 310 can be generally rectangular in shape (as illustrated). For instance, a width of the first region 310 may be substantially similar along a lateral dimension of the first region 310. For instance, the width of the first region 310 can remain generally constant along the first transmission length as light propagates through the first region 310. Additionally and/or alternatively, the length and/or width of the first region 310 can be selected to provide a desired propagation pattern. As one example, a width of the first region 310 can be within a range from about 1 micrometer (μm) to about 15 micrometers. As another example, a length of the first region 310 can be within a range from about 5 micrometers to about 50 micrometers. As another example, the desired interaction can be effectuated by a particular ratio of a length of the first region 310 to a width of the first region 310. For example, if the width of the first region 310 is selected arbitrarily, the first region 310 can be an MMI region if the length of the first region 310 is a particular multiple of the width of the first region 310. For example, the length of the first region 310 can be a multiple from about three times to about six times the width of the first region 310.

The second semiconductor layer 304 (e.g., a germanium layer) of photodiode 300 can be formed on a portion of the first semiconductor layer 302, wherein the portion of the first semiconductor layer 302 on top of which the second semiconductor layer 304 is formed combine to form a second region 312 of the photodiode 300, referred to as an absorption region. The second region 312 can be characterized by a second transmission length and formed with at least a first metal contact 306 thereon. The second region 312 is coupled to the first region 310 such that light exiting the first region 310 flows into the second region 312. The second region 312 can be generally rectangular in shape (as illustrated). For instance, a width of the second region 312 may be substantially similar along a lateral dimension of the second region 312. For instance, the width of the second region 312 can remain generally constant along the second transmission length as light propagates through the second region 312.

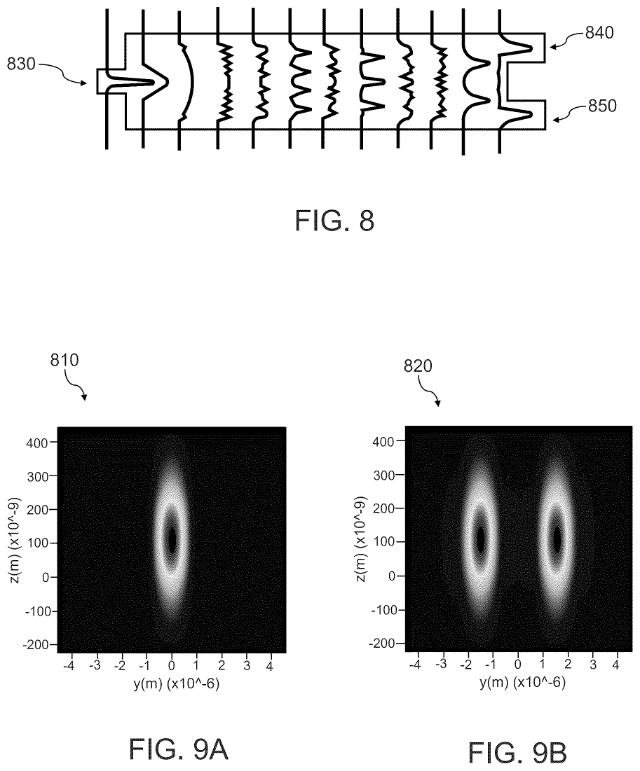

Light propagating into the first region 310 of the photodiode 300 can include one or more first optical modes and light propagating into the second region 312 of the photodiode 300 can include one or more second optical modes. The first optical mode(s) can be different from the second optical mode(s). Example aspects of a first optical mode(s) 810 and second optical mode(s) 820 are depicted in FIGS. 8 and 9A-9B. FIG. 8 depicts a flow of light within the first (MMI) region 310 of a photodiode, illustrating how light transforms from the first optical mode(s) to the second optical mode(s) as light flows left to right along the transmission length of the first region. The first optical mode(s) operable to propagate into the first region 310 of the photodiode 300 provide a first propagation pattern 810. The first propagation pattern 810 can be related to (e.g., can be) the first optical mode(s). For instance, the first propagation pattern 810 includes one or more orders of optical modes that may, for example, correspond to different wavelengths or other signals of light. The first propagation pattern 810 is substantially singular in nature as depicted in FIG. 9A. For instance, the first propagation pattern 810 is focused about a first central location 830 along a cross-section of the first region 310 of photodiode 300, as depicted in FIG. 8. For example, the first propagation pattern 810 can include a singular lobe at the first central location 830. The second optical mode(s) operable to exit the first region 310 and propagate into the second region 312 of the photodiode 300 can provide a second propagation pattern 820. The second propagation pattern 820 is substantially dual in nature as depicted in FIG. 9B. For instance, the second propagation pattern 820 can be focused about two distributed locations corresponding to a first peripheral location 840 and a second peripheral location 850 along the cross-section of the photodiode 300. As an example, the second propagation pattern 820 can include a lobe at each of the first peripheral location 840 and the second peripheral location 850. The first peripheral location 840 associated with the second propagation pattern 820 is towards a first side of the first central location 830 associated with the first propagation pattern 810, while the second peripheral location associated 850 with the second propagation pattern 820 is towards a second side (opposite the first side) of the first central location 830 associated with the first propagation pattern 810. A second propagation pattern having a dual nature is illustrated in FIG. 9B for the purposes of illustration. It should be understood that aspects of the present disclosure can provide propagation patterns in the second region 312 having any suitable nature, such as propagation patterns having greater than two lobes at greater than two peripheral locations.

By intentionally modifying and distributing the orders of optical mode(s) of the light into two peripheral locations 840, 850, modified light can then enter the second (absorption) region 312 of the photodiode 300 at locations that are distributed away from the metal contact 306 on top of the second semiconductor layer 304. Strategic positioning of the first (MMI) region 310 before the second (absorption) region 312 of the photodiode 300 serves to beneficially facilitate the redistribution of the input optical power. By selecting a specific location that ensures minimal overlap with the contact metal, absorption efficiency can be enhanced and potentially detrimental effects of optical absorption can be mitigated.

Referring still to FIGS. 3A-3C, the metal contact 306 can be configured as a terminal for the photodiode 300 and is formed on a central portion of the second semiconductor layer 304 corresponding to the second region 312. The first region is formed without a metal contact thereon. Light in the second region 312 provides an electrical signal at the metal contact 306 representative of an intensity or optical strength of light entering the photodiode 300. In some implementations, a second metal contact (not illustrated) can be formed elsewhere on the semiconductor layer 302. In some implementations, the metal contact 306 can be configured as a first terminal (e.g., anode) of the photodiode 300 and the second metal contact can be configured as a second terminal (e.g., cathode) of the photodiode 300.

Light flow through the entirety of the photodiode 300 can include the following sequence of operations: (i) light enters the waveguide region 308 of the photodiode 300 through an input port at a first end of the waveguide region 308 and travels to a second opposing end of the waveguide region 308; (ii) light expands in the first (MMI) region 310 of the photodiode 300 as it travels from a first end to an opposing second end of the first region 310 along the first transmission length; and (iii) light is absorbed from the first semiconductor layer 302 into the second semiconductor layer 304 as it travels into the second region 312 along the second transmission length. For instance, light can be absorbed into the second semiconductor layer 304 from the first semiconductor layer 302 attributing to the proximity of the first semiconductor layer 302 and the second semiconductor layer 304. As light propagates through the first semiconductor layer 302, a nonzero component of the optical mode of the propagating light can overlap with the second semiconductor layer 304. This component can leak into the second semiconductor layer 304 and can gradually provide an increased amount of light in the second semiconductor layer 304 as light propagates through the second transmission length. As used herein, “light” refers to energy of a suitable wavelength on the electromagnetic spectrum, which may include visible light and/or non-visible light, such as that emitted from a light source such as, but not limited to, a laser.

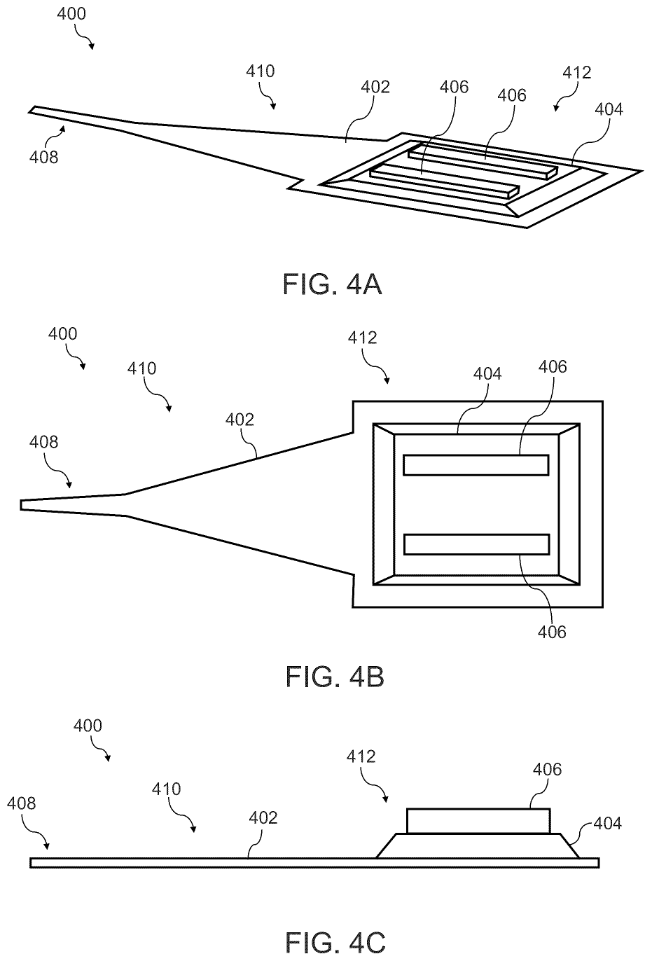

FIGS. 4A-4C variously depict a second example photodiode 400. Photodiode 400 can include a first semiconductor layer 402, a second semiconductor layer 404, a first metal contact 406 and a second metal contact 407. The first semiconductor layer (e.g., a silicon base layer) can be configured to form a waveguide region 408 for receipt of initial light into the photodiode 400. The first semiconductor layer 402 can also be configured to form a first region 410 of the photodiode 400. The first region 410 can be characterized by a first transmission length and is formed without a metal contact thereon. The first region 410 is coupled to the waveguide region 408 such that light provided as input to the waveguide region 408 flows out of the waveguide region 408 and into the first region 410. The first region 410 can be generally triangular in shape. For instance, a first width of the first region 410 at the first end can be less than a second width of the first region 410 at an opposing second end. As one example, the width of the first region 410 can increase along the first transmission length as light propagates through the first region 410.

The second semiconductor layer 404 (e.g., a germanium layer) of photodiode 400 can be formed on a portion of the first semiconductor layer 402, wherein the portion of the first semiconductor layer 402 on top of which the second semiconductor layer 404 is formed combine to form a second region 412 of the photodiode 400, referred to as an absorption region. The second region 412 can be characterized by a second transmission length and formed with at least a first metal contact 406 and a second metal contact 407 thereon. The second region 412 is coupled to the first region 410 such that light exiting the first region 410 flows into the second region 412. The second region 412 can be generally rectangular in shape. For instance, a width of the second region 412 can be substantially similar along a lateral dimension of the second region 412. For instance, the width of the second region 412 can remain generally constant along the second transmission length as light propagates through the second region 412.

Referring still to FIGS. 4A-4C, the first metal contact 406 can be configured as a first terminal (e.g., anode) for the photodiode 400 and is formed on a first peripheral portion of the second semiconductor layer 404 corresponding to the second region 412. The second metal contact 407 can be configured as a second terminal (e.g., cathode) for the photodiode 400 and is formed on a second peripheral location of the second semiconductor layer 404 corresponding to the second region 412. The first peripheral location can be opposite the second peripheral location along a dimension of the second semiconductor layer 404. Light detected across the first metal contact 406 and the second metal contact 407 in the second region 412 provides an electrical signal representative of an intensity or optical strength of light entering the photodiode 400.

In the photodiode 400 of FIGS. 4A-4C, metal contact engineering by employing the first metal contact 406 and second metal contact 407 forming the anode and/or cathode portions of the photodiode 400 can be configured to further enhance absorption efficiency of the photodiode 400. Particular design of the metal contact(s) can include selected contact geometry, thickness, or placement to reduce potential optical losses. For example, first metal contact 406 and second metal contact 407 forming the anode and cathode of the photodiode 400 can be positioned at respective locations across a surface of the photodiode 400 that are offset relative to the focused locations of the propagation pattern(s) attributable to the optical mode(s) of light propagating through the photodiode 400. In this instance, the propagation pattern of light entering the second region 412 of photodiode 400 is substantially singular in nature as depicted in FIG. 9A. It should be appreciated that the metal contact engineering optimization techniques applied in the embodiment of FIGS. 4A-4C can be employed individually or in combination (e.g., with photodiode 300 of FIGS. 3A-3C) to achieve the desired reduction in optical losses and enhance the absorption efficiency of the photodiode.

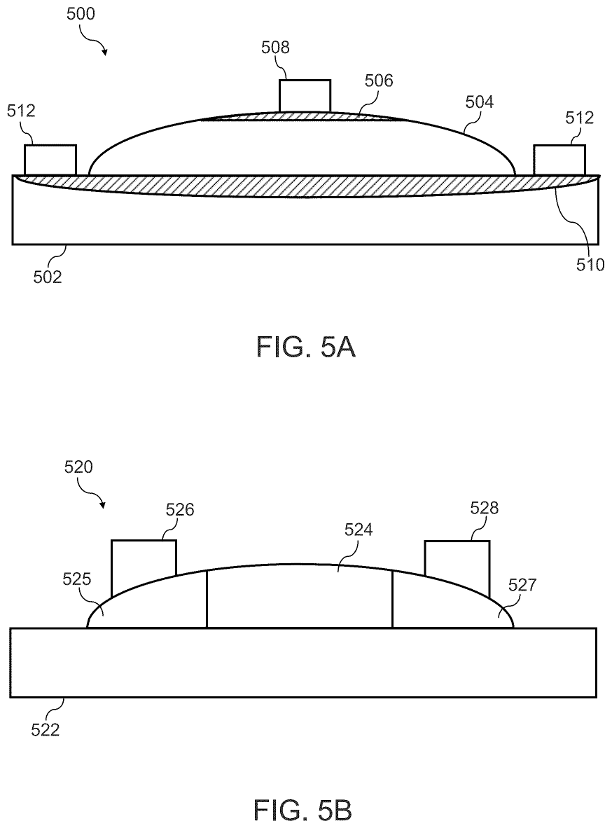

FIGS. 5A-5B provide cross-sectional views of respective first and second photodiodes with example doping of the semiconductor layers. Portions of the silicon and germanium layers can be doped with one or more doping materials to create extrinsic semiconductor areas intended for formation of electrical circuit elements. As one example, portions of the silicon layers and/or germanium layers can be doped with a n-type doping material to create n-type regions. Example n-type doping materials include, but are not limited to, phosphorus, silicon, zinc, arsenic, or other suitable material. As another example, portions of the silicon layers and/or germanium layers can be doped with a p-type doping material to create p-type regions. Example p-type doping materials include, but are not limited to, boron, silicon, zinc, indium, or other suitable dopant.

The example photodiodes of FIGS. 5A-5B can include a first region and a second region as described herein. Referring to FIG. 5A, a photodiode 500 can include a second region formed by first semiconductor layer 502 and second semiconductor layer 504. The first semiconductor layer 502 can be formed of silicon (Si) and the second semiconductor layer 504 can be formed of germanium (Ge). The second semiconductor layer 504 can include a doped p-type region 506, on top of which a first metal contact 508 is formed to create an anode (first terminal) for the photodiode 500. The first semiconductor layer 502 can include a doped n-type region 510, on top of which one or more second metal contacts 512 are formed to create a cathode (second terminal) for the photodiode 500. Collectively, the doped p-type region 506 and doped n-type region 510 form a p-n junction of the photodiode 500, which converts optical light into electrical current.

Referring to FIG. 5B, a photodiode 520 can include a second region formed by first semiconductor layer 522 and second semiconductor layer 524. The first semiconductor layer 522 can be formed of silicon (Si) and the second semiconductor layer 524 can be formed of germanium (Ge). The second semiconductor layer 524 can include a doped p-type region 525, on top of which one or more first metal contacts 526 are formed to create an anode (first terminal) for the photodiode 520. The second semiconductor layer 524 can also include a doped n-type region 527, on top of which one or more second metal contacts 528 are formed to create a cathode (second terminal) for the photodiode 520. Collectively, the doped p-type region 525 and doped n-type region 527 form a p-n junction of the photodiode 520, which converts optical light into electrical current.

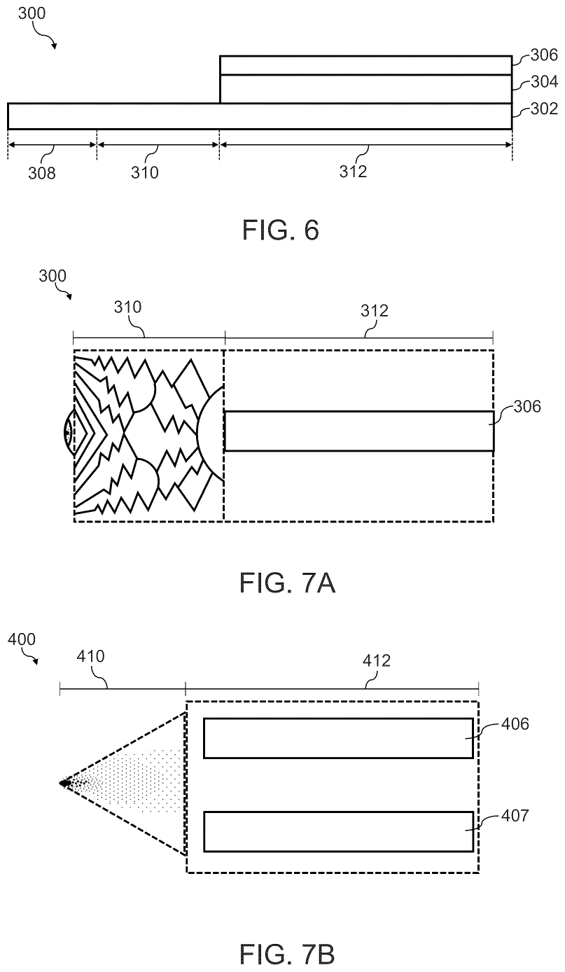

FIGS. 6 and 7A-7B depict additional aspects of the photodiode 300 and photodiode 400 examples depicted in FIGS. 3A-3C and 4A-4C respectively. For example, FIG. 6 shows a cross-sectional view of the various layers and regions of photodiode 300. FIG. 7A depicts a top view including optical engineering associated with the first (MMI) region 310 of photodiode 300 before light enters the second (absorption) region 312. FIG. 7B depicts a top view including metal contact engineering associated with the first metal contact 406 and second metal contact 407 of the second (absorption) region 412 of photodiode 400 after light enters from the first region 410.

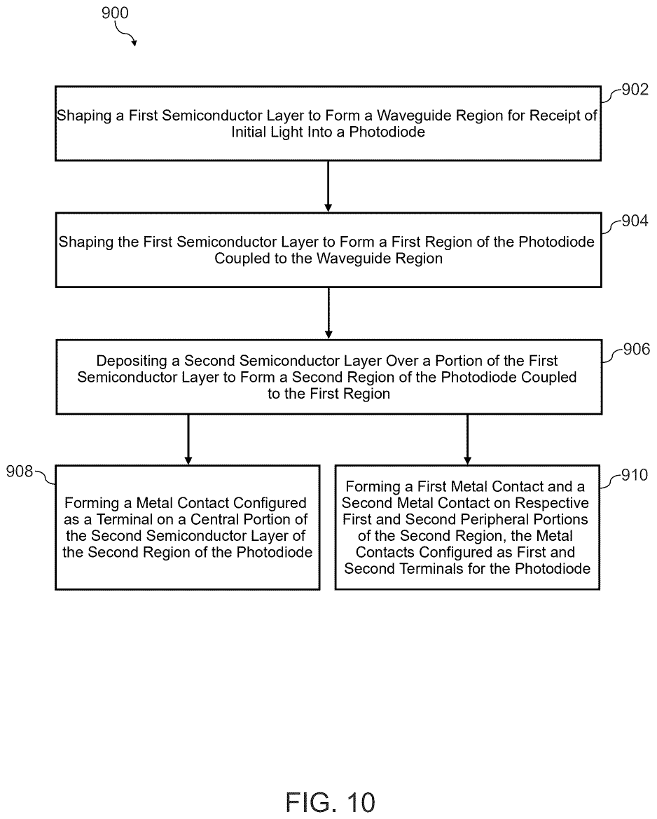

FIG. 10 illustrates a flow diagram of an example method, according to one or more example embodiments of the disclosure. The flow diagram of FIG. 10 illustrates a method 900 for manufacturing a semiconductor-based light-sensitive device such as a photodiode for a LIDAR sensor system for a vehicle, according to some implementations of the disclosure. Although shown in a particular sequence or order, unless otherwise specified, the order of the processes can be modified. Thus, the illustrated embodiments should be understood only as examples, and the illustrated processes can be performed in a different order, and some processes can be performed in parallel. Additionally, one or more processes can be omitted in various embodiments. Thus, not all processes are required in every embodiment. Other process flows are possible.

Referring to FIG. 10, at operation 902, the method 900 includes shaping a first semiconductor layer to form a waveguide region for receipt of initial light into a photodiode. The waveguide region formed at 902 can correspond, for example, to the waveguide region 308 depicted in FIGS. 3A-3C or the waveguide region 408 depicted in FIGS. 4A-4C.

At operation 904, the method 900 includes shaping a first semiconductor layer to form a first region of the photodiode coupled to the waveguide region formed at 902. The first region formed at 904 can correspond, for example, to the first region 310 depicted in FIGS. 3A-3C or the first region 410 depicted in FIGS. 4A-4C. When the first region formed at 904 corresponds to first region 310, it can be considered a multi-modal interference (MMI) region in which light entering the first region is transformed from propagating in a first propagation pattern that is substantially singular in nature to a second propagation pattern that substantially dual in nature as depicted in FIGS. 8 and 9A-9B.

At operation 906, the method 900 can include depositing a second semiconductor layer over a portion of the first semiconductor layer to form a second region of the photodiode coupled to the first region formed at 904. The second region formed at 906 can be considered an absorption region of the photodiode in which light is absorbed from the first semiconductor layer into the second semiconductor layer. The second region formed at 906 can correspond, for example, to the second region 312 depicted in FIGS. 3A-3C or the second region 412 depicted in FIGS. 4A-4C. Light propagating into the first region of the photodiode formed at 904 can include one or more first optical modes and light propagating into the second region of the photodiode formed at 906 can include one or more second optical modes, the second optical modes being different from the first optical modes.

The method 900 can then proceed to one of operations 908 or 910. At operation 908, the method 900 can include forming a metal contact configured as a terminal for the photodiode. The metal contact can be formed on a central portion of the second semiconductor layer corresponding to the second region. The metal contact formed at 908 can correspond, for example, to the metal contact 306 depicted in FIGS. 3A-3C.

At operation 910, the method 900 can include forming a first metal contact configured as a first terminal for the photodiode and a second metal contact configured as a second terminal for the photodiode. The first metal contact can be formed on a first peripheral portion of the second semiconductor layer corresponding to the second region, while the second metal contact can be formed on a second peripheral portion of the second semiconductor layer corresponding to the second region. The first and second metal contacts formed at 910 can correspond, for example, to the first metal contact 406 and second metal contact 407 depicted in FIGS. 4A-4C.

Aspects of the disclosure have been described in terms of illustrative implementations thereof. Numerous other implementations, modifications, or variations within the scope and spirit of the appended claims can occur to persons of ordinary skill in the art from a review of this disclosure. Any and all features in the following claims can be combined or rearranged in any way possible. Accordingly, the scope of the present disclosure is by way of example rather than by way of limitation, and the subject disclosure does not preclude inclusion of such modifications, variations or additions to the present subject matter as would be readily apparent to one of ordinary skill in the art. Moreover, terms are described herein using lists of example elements joined by conjunctions such as “and,” “or,” “but,” etc. It should be understood that such conjunctions are provided for explanatory purposes only. Lists joined by a particular conjunction such as “or,” for example, can refer to “at least one of” or “any combination of” example elements listed therein, with “or” being understood as “and/or” unless otherwise indicated. Also, terms such as “based on” should be understood as “based at least in part on.” As used herein, “about” in conjunction with a stated numerical value is intended to refer inclusively to within twenty percent of the stated numerical value, except where otherwise indicated.

Those of ordinary skill in the art, using the disclosures provided herein, will understand that the elements of any of the claims, operations, or processes discussed herein can be adapted, rearranged, expanded, omitted, combined, or modified in various ways without deviating from the scope of the present disclosure. Some of the claims are described with a letter reference to a claim element for exemplary illustrated purposes and is not meant to be limiting. The letter references do not imply a particular order of operations. For instance, letter identifiers such as (a), (b), (c), . . . , (i), (ii), (iii), . . . , etc. can be used to illustrate operations. Such identifiers are provided for the ease of the reader and do not denote a particular order of steps or operations. An operation illustrated by a list identifier of (a), (i), etc. can be performed before, after, or in parallel with another operation illustrated by a list identifier of (b), (ii), etc.

The following describes the technology of this disclosure within the context of a LIDAR system and an autonomous vehicle for example purposes only. As described herein, the technology described herein is not limited to an autonomous vehicle and can be implemented for or within other systems, autonomous platforms, and other computing systems.

What is claimed is:

1. A photodiode comprising:
a first semiconductor layer configured to form a waveguide region for receipt of initial light into the photodiode and a first region of the photodiode coupled to the waveguide region; and
a second semiconductor layer formed on a portion of the first semiconductor layer, wherein the first semiconductor layer and the second semiconductor layer form a second region of the photodiode coupled to the first region;
wherein light propagating into the first region of the photodiode comprises one or more first optical modes and light propagating into the second region of the photodiode comprises one or more second optical modes, the second optical modes being different from the first optical modes.

2. The photodiode of claim 1, wherein the one or more first optical modes provide at the first region a first propagation pattern that is substantially singular in nature and focused about a first central location along a cross-section of the photodiode.

3. The photodiode of claim 2, wherein the one or more second optical modes provide at the second region a second propagation pattern that is substantially dual in nature and focused about two distributed locations corresponding to a first peripheral location and a second peripheral location along the cross-section of the photodiode.

4. The photodiode of claim 1, comprising:
a first metal contact configured as a first terminal for the photodiode formed on a portion of the second semiconductor layer corresponding to the second region.

5. The photodiode of claim 1, wherein the first region is formed without a metal contact thereon.

6. The photodiode of claim 4, wherein the first metal contact is formed on a central portion of the second semiconductor layer corresponding to the second region.

7. The photodiode of claim 4, wherein the second semiconductor layer includes a doped p-type region on top of which the first metal contact is formed to create the first terminal for the photodiode.

8. The photodiode of claim 4, wherein:
the first metal contact is formed on a first peripheral portion of the second semiconductor layer corresponding to the second region; and
the photodiode comprises a second metal contact formed on a second peripheral portion of the second semiconductor layer, the second metal contact configured as a second terminal for the photodiode formed on a portion of the second semiconductor layer corresponding to the second region.

9. The photodiode of claim 8, wherein the first semiconductor layer includes a doped n-type region on top of which the second metal contact is formed to create the second terminal for the photodiode.

10. The photodiode of claim 9, wherein the doped p-type region and the doped n-type region form a p-n junction of the photodiode, the p-n junction configured to convert optical light into electrical current.

11. The photodiode of claim 1, wherein the first semiconductor layer includes silicon and the second semiconductor layer includes germanium.

12. A light detection and ranging (LIDAR) sensor system, the LIDAR system comprising:
a photodiode, comprising:
a first semiconductor layer configured to form a waveguide region for receipt of initial light into the photodiode and a first region of the photodiode coupled to the waveguide region; and
a second semiconductor layer formed on a portion of the first semiconductor layer, wherein the first semiconductor layer and the second semiconductor layer form a second region of the photodiode coupled to the first region; and
wherein light propagating into the first region of the photodiode comprises one or more first optical modes and light propagating into the second region of the photodiode comprises one or more second optical modes, the second optical modes being different from the first optical modes.

13. The LIDAR sensor system of claim 12, wherein the one or more first optical modes provide at the first region a first propagation pattern that is substantially singular in nature and focused about a first central location along a cross-section of the photodiode.

14. The LIDAR sensor system of claim 13, wherein the one or more second optical modes provide at the second region a second propagation pattern that is substantially dual in nature and focused about two distributed locations corresponding to a first peripheral location and a second peripheral location along the cross-section of the photodiode.

15. The LIDAR sensor system of claim 12, further comprising:
a first metal contact configured as a first terminal for the photodiode formed on a portion of the second semiconductor layer corresponding to the second region.

16. The LIDAR sensor system of claim 15, wherein the first region is formed without a metal contact thereon.

17. The LIDAR sensor system of claim 15, wherein the first metal contact is formed on a peripheral portion of the second semiconductor layer corresponding to the second region.

18. The LIDAR sensor system of claim 17, further comprising:
a second metal contact configured as a second terminal for the photodiode formed on a portion of the first semiconductor layer.

19. The LIDAR sensor system of claim 12, wherein:
the first semiconductor layer comprises silicon; and
the second semiconductor layer comprises germanium.

20. A detector for a light detection and ranging (LIDAR) sensor system, the detector comprising:
a photodiode, comprising:
a first semiconductor layer configured to form a waveguide region for receipt of initial light into the photodiode and a first region of the photodiode coupled to the waveguide region; and
a second semiconductor layer formed on a portion of the first semiconductor layer, wherein the first semiconductor layer and the second semiconductor layer form a second region of the photodiode coupled to the first region;
wherein light propagating into the first region of the photodiode comprises one or more first optical modes and light propagating into the second region of the photodiode comprises one or more second optical modes, the second optical modes being different from the first optical modes.
